(19) United States
(12) Patent Application Publication
(10) Pub. No.: US 2014/0082937 A1
(43) Pub. Date: Mar. 27, 2014

(54) METHOD OF MANUFACTURING RIGID FLEXIBLE PRINTED CIRCUIT BOARD

(71) Applicant: Samsung Electro-Mechanics Co., Ltd., Suwon (KR)

(72) Inventors: Jung Yong Park, Busan (KR); Seok Cheol Song, Busan (KR); Myong Keun Jung, Busan (KR); Jae Woo Joung, Busan (KR)

(73) Assignee: Samsung Electro-Mechanics Co., Ltd., Suwon (KR)

(21) Appl. No.: 14/034,000

(22) Filed: Sep. 23, 2013

(30) Foreign Application Priority Data
Sep. 27, 2012 (KR) 10-2012-0107706

(51) Int. Cl. H05K 3/46

(52) U.S. Cl. CPC H05K 3/4644
USPC 29/847

(57) ABSTRACT

Disclosed herein is a method of manufacturing a rigid flexible printed circuit board, including: preparing a flexible substrate having an inner layer circuit pattern formed on one surface or both surfaces thereof and divided into a rigid region and a flexible region; forming a protective layer in the flexible region of the flexible substrate; forming a coverlay so as to expose the protective layer on one surface of the flexible substrate; stacking a rigid insulating layer in the rigid region and stacking a metal layer in the protective layer and the rigid insulating layer; forming an outer layer circuit layer by patterning the metal layer and removing the metal layer in the flexible region; and removing the protective layer.

### CROSS REFERENCE(S) TO RELATED APPLICATIONS

This application claims the benefit under 35 U.S.C. Section 119 of Korean Patent Application Serial No. 10-2012-0107706 entitled “Method of Manufacturing Rigid Flexible Printed Circuit Board” filed on Sep. 27, 2012, which is hereby incorporated by reference in its entirety into this application.

### BACKGROUND OF THE INVENTION

1. Technical Field

The present invention relates to a method of manufacturing a rigid flexible printed circuit board, and more particularly, to a method of manufacturing a rigid flexible printed circuit board capable of reducing defects due to foreign materials during manufacturing by forming a protective layer in a flexible region.

2. Description of the Related Art

Generally, a printed circuit board (PCB) is a circuit board which serves to electrically connect or mechanically fix predetermined electronic components and is configured to include an insulating layer formed of an insulating material such as phenol resin, epoxy resin, and the like, and a copper clad layer attached to the insulating layer and formed with predetermined wiring patterns.

Here, the printed circuit board is sorted into a single PCB in which the wiring patterns are formed only on one surface of the insulating layer, a double PCB in which the wiring patterns are formed on both surfaces of the insulating layer, and a multi layer PCB in which the wiring patterns are formed in a multi layer by stacking the insulating layer formed with the wiring patterns in plural.

Recently, as a demand for small, slim, and high-density electronic products is increased, the multi layer printed circuit board, in particular, a rigid flexible printed circuit board (RFPCB) having flexibility a product that can be marketed as a printed circuit board and has continuously received attention for marketability.

The rigid flexible printed circuit board uses both of the existing multi layer printed circuit board technology and flexible printed circuit board technology and can implement wiring having a three-dimensional structure and facilitate assembling to have been widely used for an apparatus to which a design of a high integration circuit such as a notebook, a digital camera, a camcorder, a mobile communication terminal, and the like, is applied. In this case, the multi layer printed circuit board or the flexible printed circuit board has involved a space problem, a connection reliability problem, and a component mounting problem due to the use of a separate connector, but the rigid flexible printed circuit board can resolve these problems and perform both a function of the component mounting substrate and an interface function.

The configuration of the rigid flexible printed circuit board includes a flexible region in which circuit patterns are formed on a flexible film made of polyester, polyimide, and the like, having flexibility and a rigid region with the increased physical hardness by stacking an insulating layer on the flexible film.

The rigid flexible printed circuit board is manufactured by forming the circuit patterns on the flexible insulating layer and the rigid insulating layer so that a portion in which the rigid insulating layers are stacked is formed as the rigid substrate part and a portion in which the rigid insulating layer is not stacked is formed as a flexible substrate part, by selectively stacking the rigid insulating layers on the flexible insulating layer.

However, the flexible substrate part in the region in which the circuit patterns are formed may have defects, due to the sticking of foreign materials generated during a process of stacking the rigid insulating layer and forming the rigid substrate part to the region in which the circuit patterns are formed.

### SUMMARY OF THE INVENTION

An object of the present invention is to prevent the occurrence of defects due to foreign materials during a process of manufacturing a rigid flexible printed circuit board and simplifying a manufacturing process thereof to shorten a lead time.

According to an exemplary embodiment of the present invention, there is provided a method of manufacturing a printed circuit board, including: preparing a flexible substrate having an inner layer circuit pattern formed on one surface or both surfaces thereof and divided into a rigid region and a flexible region; forming a protective layer in the flexible region of the flexible substrate; forming a coverlay so as to expose the protective layer on one surface of the flexible substrate; stacking a rigid insulating layer in the rigid region and stacking a metal layer in the protective layer and the rigid insulating layer; forming an outer layer circuit layer by patterning the metal layer and removing the metal layer in the flexible region; and removing the protective layer.

The preparing of the flexible substrate having the inner layer circuit pattern formed on one surface or both surfaces thereof and divided into the rigid region and the flexible region may include: preparing the flexible substrate having a flexible resin layer formed thereon and a copper clad layer formed on one surface or both surfaces of the flexible resin layer and forming an inner layer circuit pattern by performing exposing, developing, and etching processes on the flexible substrate may be performed.

The forming of the protective layer in the flexible region of the flexible substrate may include: applying the protective layer to the flexible substrate in a non-hard state and hardening the protective layer.

The protective layer may be made of an alkaline material.

In the hardening of the protective layer, the protective layer may be hardened by any one of infrared rays, ultraviolet rays, and heat.

The forming of the coverlay so as to expose the protective layer on one surface of the flexible substrate may include: tack welding a coverlay exposing the protective layer to one surface of the flexible substrate; tack welding a shielding film for shielding electromagnetic waves to an upper surface of the coverlay; and molding both of the coverlay and the shielding film may be performed.

The method of manufacturing a printed circuit board may further include: after the molding of both of the coverlay and the shielding film, forming an etching resist on an upper surface of the shielding film.

In the stacking of the rigid insulating layer in the rigid region and the stacking of the protective layer and the rigid insulating layer, the rigid insulating layer may be stacked in the rigid region in which the protective layer is not formed and the metal layer may be stacked on an upper surface of the rigid insulating layer so as to cover the protective layer.

In the forming of the outer layer circuit layer by patterning the metal layer and the removing the metal layer in the flexible region, the metal layer may be selectively etched by an etching solution.

In the removing of the protective layer, the protective layer may be peeled off by an alkaline peeling solution.

### BRIEF DESCRIPTION OF THE DRAWINGS

FIG. 1 is a flow chart illustrating a method of manufacturing a rigid flexible printed circuit board according to an exemplary embodiment of the present invention.

FIGS. 2 to 8 are diagrams sequentially describing a method of manufacturing a rigid flexible printed circuit board according to the exemplary embodiment of the present invention.

### DESCRIPTION OF THE PREFERRED EMBODIMENTS

Hereinafter, exemplary embodiments of the present invention will be described in detail with reference to the accompanying drawings. However, this is only by way of example and therefore, the present invention is not limited thereto.

When technical configurations known in the related art are considered to make the contents obscure in the present invention, the detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

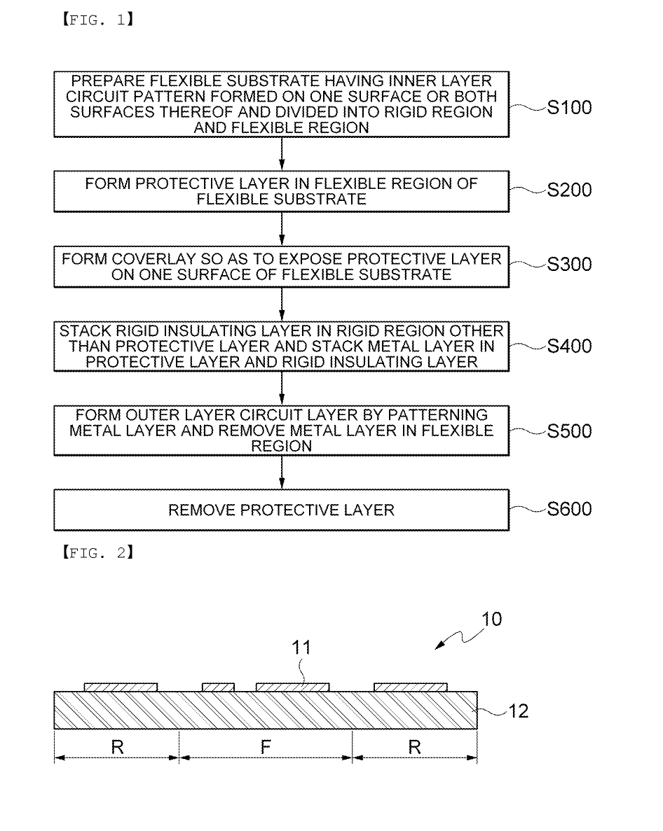

Hereinafter, a method of manufacturing a rigid flexible printed circuit board according to exemplary embodiments of the present invention will be described below with reference to FIGS. 1 to 8.

FIG. 1 is a flow chart illustrating a method of manufacturing a rigid flexible printed circuit board according to an exemplary embodiment of the present invention, and FIGS. 2 to 8 are diagrams sequentially describing a method of manufacturing a rigid flexible printed circuit board according to the exemplary embodiment of the present invention.

As illustrated in FIGS. 1 to 8, the method of manufacturing a rigid flexible printed circuit board according to an exemplary embodiment of the present invention includes preparing a flexible substrate 10 having an inner layer circuit pattern 11 formed on one surface or both surfaces thereof and divided into a rigid region R and a flexible region F (S100), forming a protective layer 20 in the flexible region F of the flexible substrate 10 (S200), forming a coverlay 30 on one surface of the flexible substrate 10 so as to expose the protective layer 20 (S300), stacking the rigid insulating layer 50 in the rigid region R and stacking a metal layer 60 on the protective layer 20 and a rigid insulating layer 50 (S400), forming an outer layer circuit layer 61 by patterning the metal layer 60 and removing the metal layer 60 in the flexible region F (S500), and removing the protective layer 20 (S600).

First, as illustrated in FIG. 2, the flexible substrate 10 having the inner layer circuit patterns 11 formed on one surface or both surfaces thereof and divided into the rigid region R and the flexible region F may be prepared (S100).

Here, the flexible substrate 10 configured of a flexible resin layer 12 and a copper clad layer formed on one surface of the flexible resin layer 12 is prepared and an inner layer circuit pattern 11 is formed by performing the exposing, developing, and etching processes on the copper clad layer 11 of the flexible substrate 10.

In this case, the flexible resin layer 12 corresponds to a core layer of the flexible substrate 11 and may be made of a flexible resin material. For example, a polyimide resins, polyamide resins, or polyester resins such as polyimide resin, polyether imide resin, polyamide imide resin, and the like, may be used, in particular, the polyimide resins may be preferably used.

Further, the inner layer circuit pattern 11 is formed by patterning the copper clad layer formed on the flexible resin layer 12 using the exposing, developing, and etching processes and may be patterned to have a predetermined shape according to a design of a designer.

Meanwhile, the flexible substrate 10 illustrated in FIG. 2 cannot be divided into the rigid region R and the flexible region F in terms of appearance, but in the manufacturing of the substrate, two regions as any region scheduled in the design process of the substrate may be divided in terms of appearance by stacking the rigid insulating layer 50 therein. Further, as described below, the region in which the protective layer 20 is formed may be divided into the flexible region F.

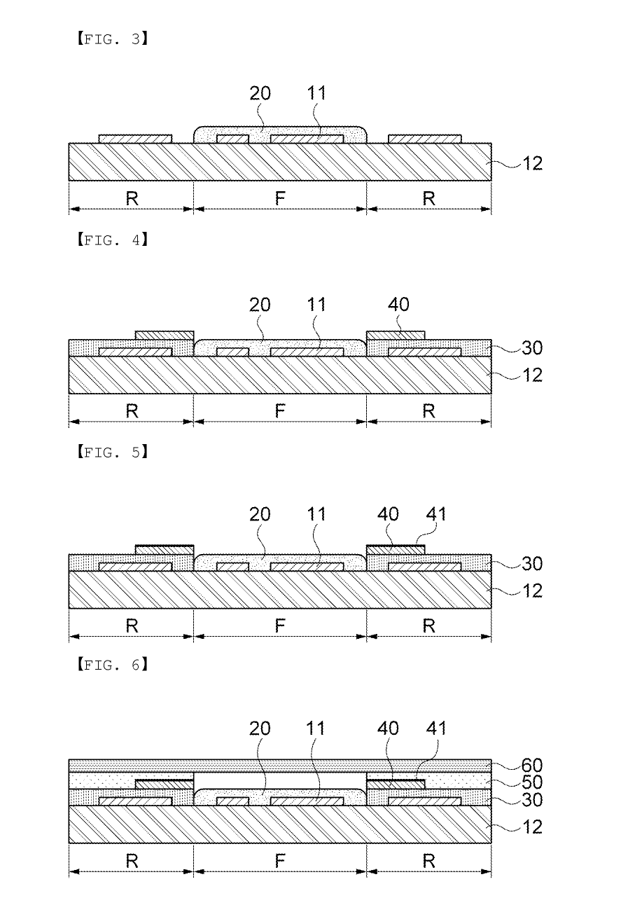

Next, as illustrated in FIG. 3, the forming of the protective layer 20 in the flexible region F of the flexible substrate 10 may be performed (S200).

Here, the protective layer 20 is to protect the inner layer circuit pattern 11 formed in the flexible region F of the flexible substrate 10 from the external environment. In particular, it is possible to prevent the foreign materials occurring during the process to be described below from being stuck to the inner layer circuit pattern 11. Meanwhile, the protective layer 20 may be made of an etching resist material to prevent the inner layer circuit pattern 11 from being damaged from an etching solution when the etching process is performed during the manufacturing of the substrate.

In this case, the protective layer 20 is applied to the upper surface of the flexible region F in a non-hard state and is then hardened in a semi-hardening state. In particular, the protective layer 20 is applied to cover the inner layer circuit pattern 11 in the flexible region F.

Further, the hardening of the protective layer 20 may be hardened by any one of infrared rays, ultraviolet rays, or heat.

Further, the protective layer 20 may be made of an alkaline material and the protective layer 20 may be made of an alkaline material and may be removed by an alkaline aqueous solution during the process of removing the protective layer 20 that is a subsequent process.

Next, as illustrated in FIG. 4, the forming of the coverlay 30 may be performed to expose the protective layer 20 on one surface of the flexible substrate 10.

Here, in the forming of the coverlay 30, the coverlay 30 exposing the protective layer 20 is tack-welded on one surface of the flexible substrate 10 and the shielding film 40 shielding electromagnetic waves is tack-welded on the coverlay 30 and then, the coverlay 30 and the shielding film 40 are simultaneously molded.

That is, the shielding film 40 and the coverlay 30 are stacked in the inner layer together and are molded at a time, such that the manufacturing process may be simplified, the lead time may be shortened, and the manufacturing costs may be saved.

Here, the coverlay 30 may partially opened so that the protective layer 20 is exposed.

In this case, the coverlay 30 is to protect the inner layer circuit pattern 11 formed in the rigid region R that is an area in which the protective layer 20 is not formed from protecting from the external environment and may be made of the flexible, heat-resistant, and insulating materials.

For example, the coverlay 30 is made of polyimide resin.

Further, the coverlay 30 may be formed in a film type having an adhesive applied to one surface thereof.

Further, the shielding film 40 is to shield the electromagnetic waves and is formed on the upper surface of the coverlay 30 and may be formed in a film type having an adhesive applied to one surface thereof, similar to the coverlay 30.

That is, the shielding film 40 shields the electromagnetic waves from being shielded from the outside to minimize the effect on the electromagnetic waves.

Meanwhile, as illustrated in FIG. 5, after the shielding film 40 is molded and then, the upper surface of the shielding film 40 is formed with an etching resist 41.

The etching resist 41 is to protect the shielding film 40 and in the manufacturing of the substrate, prevents the shielding film 40 from being damaged due to the etching solution when the etching process using the etching solution is performed as the subsequent process.

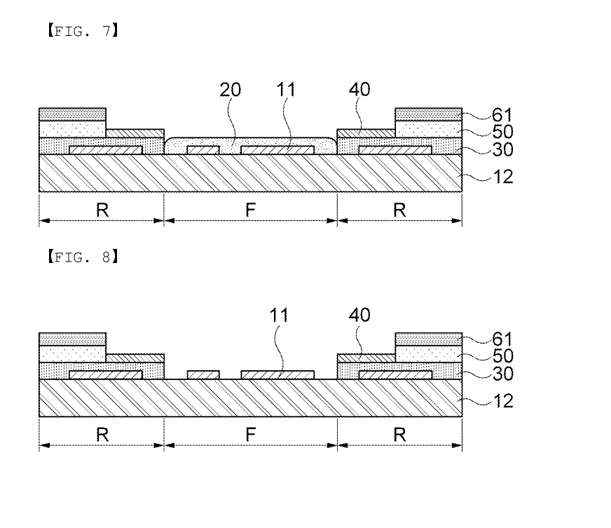

Next, as illustrated in FIG. 6, the stacking of the rigid insulating layer 50 in the rigid region R and the stacking of the metal layer 60 on the protective layer 20 and the rigid insulating layer 50 are performed.

Here, the rigid insulating layer 50 is stacked in the rigid region R in which the protective layer 20 is not formed.

In this case, as the rigid insulating layer 50, a prepreg (PPG) or a bonding sheet that is melted when heat is applied to an insulating layer having predetermined stiffness and may be formed so that the corresponding region has rigidity by stacking the rigid insulating layer 50.

Thereafter, the metal layer 60 is stacked on the upper surface of the rigid insulating layer 50.

Here, the metal layer 60 is stacked on the upper surface of the rigid insulating layer 50 so as to cover both of the upper portion of the protective layer 20 and the upper surface of the insulating layer 50.

Next, as illustrated in FIG. 7, the forming of the outer layer circuit layer 61 by patterning the metal layer 60 and the removing of the metal layer 60 in the flexible region F may be performed (S500).

Here, a dry film corresponding to an outer layer circuit pattern is formed on the upper surface of the metal layer 60 and the metal layer 60 is selectively removed by using the etching solution.

In this case, the dry film corresponding to the outer layer circuit pattern may be formed by an exposing process using an artwork film and ultraviolet rays and a developing process using a developer.

When the dry film is formed as described above and the etching solution is provided, the exposed metal layer 60 may be partially removed without being covered by the dry film to form the outer layer circuit layer.

In this case, an acid solution is used as the etching solution for selectively removing the metal layer 60 and an acid solution having excellent reactivity with metal is used as the etching solution so as to remove only the metal layer 60 by the chemical reaction with the etching solution.

Further, the protective layer 20 and the shielding film 40 is exposed to the outside by removing a portion covering the protective layer 20 and the upper portion of the shielding film 40 when the metal layer 60 is selectively removed.

Next, as illustrated in FIG. 8, the removing of the protective layer 20 may be performed (S600).

Here, the protective layer 20 is peeled off using a peeling solution, wherein the peeling solution, which is an alkaline solution, peels off the protective layer 20 by a chemical method.

In this case, the flexible region F and a part of the inner layer circuit pattern 11 are exposed to the outside by removing the protective layer 20.

That is, when the protective layer 20 is peeled off, the foreign materials stuck to the upper portion of the protective layer 20 are removed together during the process of manufacturing a substrate, such that the occurrence of defects due to the foreign materials may be reduced.

As set forth above, according to the exemplary embodiments of the present invention, the method of manufacturing a rigid flexible printed circuit board can reduce the occurrence of foreign materials and the occurrence of defects due to foreign materials only by changing the process sequence and simplify the manufacturing process by molding the coverlay and the shielding film at a time, thereby shortening the lead time and saving the manufacturing costs.

As described above, the present invention will be described with reference to the exemplary embodiments, but is not limited thereto. It can be apparent to those skilled in the art that the exemplary embodiments of present invention can be variously changed and applied within the scope of the present invention without departing from the technical idea of the present invention.

Therefore, the protection scope of the present invention must be construed by the appended claims and it should be construed that all spirits within a scope equivalent thereto are included in the appended claims of the present invention.

What is claimed is:

1. A method of manufacturing a printed circuit board, comprising:
preparing a flexible substrate having an inner layer circuit pattern formed on one surface or both surfaces thereof and divided into a rigid region and a flexible region;
forming a protective layer in the flexible region of the flexible substrate;
forming a coverlay so as to expose the protective layer on one surface of the flexible substrate;
stacking a rigid insulating layer in the rigid region and stacking a metal layer in the protective layer and the rigid insulating layer;
forming an outer layer circuit layer by patterning the metal layer and removing the metal layer in the flexible region; and
removing the protective layer.

2. The method according to claim 1, wherein the preparing of the flexible substrate having the inner layer circuit pattern formed on one surface or both surfaces thereof and divided into the rigid region and the flexible region includes:
preparing the flexible substrate having a flexible resin layer formed thereon and a copper clad layer formed on one surface or both surfaces of the flexible resin layer; and
forming an inner layer circuit pattern by performing exposing, developing, and etching processes on the flexible substrate.

3. The method according to claim 1, wherein the forming of the protective layer in the flexible region of the flexible substrate includes:
applying the protective layer to the flexible substrate in a non-hard state; and
hardening the protective layer.

4. The method according to claim 3, wherein the protective layer is made of an alkaline material.

5. The method according to claim 3, wherein in the hardening of the protective layer, the protective layer is hardened by any one of infrared rays, ultraviolet rays, and heat.

6. The method according to claim 1, wherein the forming of the coverlay so as to expose the protective layer on one surface of the flexible substrate includes:
tack welding a coverlay exposing the protective layer to one surface of the flexible substrate;
tack welding a shielding film for shielding electromagnetic waves to an upper surface of the coverlay; and
molding both of the coverlay and the shielding film.

7. The method according to claim 1, further comprising, after the molding of both of the coverlay and the shielding film, forming an etching resist on an upper surface of the shielding film.

8. The method according to claim 1, wherein in the stacking of the rigid insulating layer in the rigid region other than the protective layer and the stacking of the metal layer in the protective layer and the rigid insulating layer, the rigid insulating layer is stacked in the rigid region in which the protective layer is not formed and the metal layer is stacked on an upper surface of the rigid insulating layer so as to cover the protective layer.

9. The method according to claim 1, wherein in the forming of the outer layer circuit layer by patterning the metal layer and the removing the metal layer in the flexible region, the metal layer is selectively etched by an etching solution.

10. The method according to claim 1, wherein in the removing of the protective layer, the protective layer is peeled off by an alkaline peeling solution.
